(19) United States
(12) Patent Application Publication
(10) Pub. No.: US 2019/0257142 A1
(43) Pub. Date: Aug. 22, 2019

(54) SYSTEM AND METHOD FOR A MODULAR DOOR STRUCTURE

(71) Applicant: RUSSET LABS, LLC, Sherborn, MA (US)

(72) Inventors: JEAN BERNARD KOEHL, SHERBORN, MA (US); ROBERT S. FREEMAN, FOREST, VA (US); XAVIER HUMEL, PARIS (FR)

(73) Assignee: RUSSET LABS, LLC, SHERBORN, MA (US)

(21) Appl. No.: 16/274,544

(22) Filed: Feb. 13, 2019

Related U.S. Application Data
(60) Provisional application No. 62/631,821, filed on Feb. 18, 2018.

(51) Int. Cl. E06B 7/28; E05D 11/00; E06B 3/70; E06B 3/72; H05K 7/02

(52) U.S. Cl. CPC E06B 7/28; E05D 11/0081; E06B 3/7003; E06B 3/72; E06B 2003/7011; E05Y 2900/132; E06B 2003/7046; E06B 2003/7049; H05K 7/02

(57) ABSTRACT

A system for a modular door for a building structure includes a door skeleton, an electrical interface, and a communication interface. The door skeleton includes one or more removable modular structures. At least one of the modular structures includes one or more electronic components and at least one of the electronic components is configured to receive and transmit electrical signals and data via the electrical interface and the communication interface, respectively.

### CROSS REFERENCE TO RELATED CO-PENDING APPLICATIONS

This application claims the benefit of U.S. provisional application Ser. No. 62/631,821 filed on Feb. 18, 2018 and entitled SYSTEM AND METHOD FOR A MODULAR DOOR STRUCTURE, which is commonly assigned and the contents of which are expressly incorporated herein by reference.

### FIELD OF THE INVENTION

The present invention relates to a system and a method for a modular door structure, and more particularly to a modular door structure with integrated electrical and information components and networks.

### BACKGROUND OF THE INVENTION

In most buildings, doors are used for providing access into and out of the building and for providing access into and out of partitioned sections within the building. Buildings also include wiring, connectors, and electrical and electronic devices for providing power and communications to the entire building and to the partitioned sections. Most of the wiring, connectors, and electrical and electronic devices are built into the building walls or are externally attached to the building walls. These type of built-in wiring, connectors and devices form a fixed building infrastructure that is difficult to change, upgrade and update. At the same time, several of the building electrical and electronic devices and connectors and some of the wiring become obsolete in very short time and they need to be frequently updated and upgraded. Therefore, there is a need for a flexible building infrastructure that provides wiring, connectors and electrical and electronic devices that can be easily connected, disconnected, upgraded, updated, and programmed without changing the existing building walls.

### SUMMARY OF THE INVENTION

In general, in one aspect, the invention features a system for a modular door for a building structure including a door skeleton, an electrical interface, and a communication interface. The door skeleton includes one or more removable modular structures. At least one of the modular structures includes one or more electronic components and at least one of the electronic components is configured to receive and transmit electrical signals and data via the electrical interface and the communication interface, respectively.

Implementations and advantages of this aspect of the invention may include one or more of the following features. The electrical interface and the communication interface are external to the door skeleton, or are integrated within the door skeleton. The electrical interface and the communication interface transmit and receive electrical signals and data to the electronic components via an electrical connector and a communication connector, respectively, and the electrical connector and the communication connector pass through a door hinge. One of the electronic components comprises a wireless network repeater, or a microprocessor unit. The electronic components comprise one of a bi-directional camera, a bi-directional microphone, a motion detector, a smoke detector, a carbon monoxide detector, a temperature detector, a speaker, a display, a battery, a power module manager, a modem, a router, a memory storage device, software stored in a storage device, distributed power storage, electronic noise cancelling device, door lock controller, pet access control, air quality sensor, allergen sensor, environmental handler, thermostat, light switch, smart communication device, voice activated and voice recognition device, and a sound alarm. The door skeleton further includes a strike jamb, a hinge jamb, a top extender, a bottom extender and one or more molding structures and the molding structures interdigitate with each other and form a center portion of the door skeleton. At least one of the molding structures includes a central opening and the central opening is sized to slidably receive one or more of the removable modular structures. The strike jamb, the hinge jamb, the top extender, the bottom extender, and the one or more molding structures are held together via one or more rods. The strike jamb, the hinge jamb, the top extender, the bottom extender, and the one or more molding structures are held together via mortise and tenon joints. Each of the molding structures includes one or more crenellations formed on a top surface and a bottom surface of the molding structure, and adjacent crenellations are separated by a gap and the gap is shaped and sized to receive a crenellation from an adjacent molding structure. At least one of the removable modular structures includes a visible front surface and the visible front surface comprises one of an acoustic panel, glass, electric privacy glass, touch screen, lights, LED lights, mirror, LED mirror, display, a voice controlled assistant, information center, tablet holder, biometric recognition pad, voice activated device, voice recognition device, smartphone and smart tablet. The system further includes a door frame sized to receive the door skeleton and the door frame is located in an existing building structure, or in a new building structure. The system further includes a controller configured to control the one or more electronic components remotely, and the controller includes one of a smartphone, a tablet, a remote controller, or a computing device. The system further includes one or more skin surfaces configured to be applied onto the door skeleton's front and back surfaces. Each removable modular structure includes a power connector and a communication connector and the power connector and communication connector are configured to mate with a corresponding power connector and a corresponding communication connector, respectively, that are located on a surface of the hinge jamb, when the removable modular structure is fully inserted into a molding structure.

In general, in another aspect, the invention features a method for a modular door for a building structure including the following. Providing a door skeleton comprising one or more removable modular structures. Next, providing an electrical interface and a communication interface. Next, placing one or more electronic components within at least one of the removable modular structures, wherein at least one of the electronic components is configured to receive and transmit electrical signals and data via the electrical interface and the communication interface, respectively.

In general, in another aspect, the invention features a method for configuring a modular door for a building structure including the following. Providing a door configuration design application configured to present various door configuration design parameters and to generate instructions for constructing a modular door configuration based on user input. Next, providing a computing system comprising at least a processor configured to execute computer-implemented instructions of the door configuration design application. Next, providing a user interface that displays the various door configuration design parameters, wherein the door configuration parameters comprise door skeletons and electronic components. Next, selecting a door skeleton comprising one or more removable modular structures. Next, selecting one or more electronic components and placing the one or more electronic components within at least one of the removable modular structures. At least one of the electronic components is configured to receive and transmit electrical signals and data via an electrical interface connector and a communication interface connector, respectively, and wherein the electrical interface connector and the communication interface connector are located within the door skeleton.

In general, in another aspect, the invention features a system for configuring a modular door for a building structure including a door configuration design application, a computing system and a user interface. The door configuration design application is configured to present various door configuration design parameters and to generate instructions for constructing a modular door configuration based on user input. The computing system includes at least a processor configured to execute computer-implemented instructions of the door configuration design application. The user interface displays the various door configuration design parameters, and the door configuration parameters comprise door skeletons and electronic components. A door skeleton includes one or more removable modular structures and one or more electronic components located within at least one of the removable modular structures. At least one of the electronic components is configured to receive and transmit electrical signals and data via an electrical interface connector and a communication interface connector, respectively, and the electrical interface connector and the communication interface connector are located within the door skeleton.

The details of one or more embodiments of the invention are set forth in the accompanying drawings and description below. Other features, objects, and advantages of the invention will be apparent from the following description of the preferred embodiments, the drawings and from the claims.

### BRIEF DESCRIPTION OF THE DRAWINGS

Referring to the figures, wherein like numerals represent like parts throughout the several views:

FIG. 1 is a front view of the modular door structure according to this invention;

FIG. 2 is an exploded front view of the modular door structure of FIG. 1;

FIG. 3 is an exploded cross-sectional view of the modular door structure of FIG. 1;

FIG. 4 is an assembled cross-sectional view of the modular door structure of FIG. 1;

FIG. 5A is a front view of the standard molding in FIG. 1;

FIG. 5B is a perspective view of the standard molding of FIG. 5A;

FIG. 5C is a top perspective view of the standard molding of FIG. 5A;

FIG. 5D is a perspective view of the crenellation in the standard molding of FIG. 5A;

FIG. 5E is a side view of the standard molding of FIG. 5A;

FIG. 6 is a front view of the top extender of FIG. 2;

FIG. 7 is a front view of the bottom extender of FIG. 2;

FIG. 8A is a side view of the holding bolt of FIG. 4;

FIG. 8B is a side view and a top view of the holding bolt head of FIG. 8A;

FIG. 8C is a side view of the holding bolt tip of FIG. 8A;

FIG. 9A is a partially exploded perspective view of the modular door structure of FIG. 1;

FIG. 9B and FIG. 9C are enlarged views of the bottom portion of the partially exploded modular door structure of FIG. 9A;

FIG. 10A is a side view of the hinge jamb core of FIG. 9A at the side opposite the door;

FIG. 10B is a side view of the hinge jamb core of FIG. 9A at the side of the door;

FIG. 11A is a perspective view of the hinge jamb core of FIG. 9A;

FIG. 11B is a perspective view of an enlarged top portion of the hinge jamb core of FIG. 11A;

FIG. 11C is a side view of an enlarged portion of the hinge jamb core of FIG. 11A;

FIG. 11D is a side view of an enlarged area A of the hinge jamb core of FIG. 11A near the power hinge;

FIG. 12A is a side view of the hinge jamb hollow member of FIG. 9A at the side opposite the door;

FIG. 12B is a side view of the hinge jamb hollow member of FIG. 9A at the side of the door;

FIG. 13A is a side view of the strike jamb of FIG. 3 at the side of the door;

FIG. 13B is a side view of the strike jamb of FIG. 3 at the opposite side of the door;

FIG.13C is an enlarged side view of the knob opening 111 of FIG. 13B;

FIG. 14A is a perspective view of a module tray of this invention;

FIG. 14B is a front view of the module tray of FIG. 14A;

FIG. 15A is a front view of the module tray insertion into the door skeleton;

FIG. 15B is an enlarged view of area D of FIG. 15A;

FIG. 16 is a perspective view of the top and bottom extenders of in the modular door of FIG. 1;

FIG. 17 is a wiring diagram of the modular door of FIG. 1;

FIG. 18 depicts examples of modules for the modular door of FIG. 1;

FIG. 19 depicts examples of skins for the modular door of FIG. 1;

FIG. 20 depicts additional examples of skins for the modular door of FIG. 1;

FIG. 21 depicts the x-shaped cavities used for the attachment of the skins onto the surfaces of the modular door of FIG. 1;

FIG. 22 depicts various methods for the attachment of the skins onto the surfaces of the modular door of FIG. 1;

FIG. 23 depicts a user interface for the modular door configuration application;

FIG. 24 depicts the system for selecting and controlling the modular door configuration;

FIG. 25 depicts schematic diagrams of a single source Wi-Fi network and a multiple source door-enabled Wi-Fi network;

FIG. 26 depicts a computer system used for running the applications and methods of this invention;

FIG. 27A is a front view of another embodiment of the modular door structure according to this invention;

FIG. 27B is a side perspective view of the embodiment of the modular door structure of FIG. 27A;

FIG. 28 is a front view of a top panel of the embodiment of the modular door structure of FIG. 27A;

FIG. 29 is a front view of a middle panel of the embodiment of the modular door structure of FIG. 27A; and

FIG. 30 is a front view of a bottom panel of the embodiment of the modular door structure of FIG. 27A.

### DETAILED DESCRIPTION OF THE INVENTION

The invention features a modular door system that provides a hub or portal with variable power and multiple locations to extend the function of a door from a simple blocking or obstructing device to a multi-sensing, multi-functioning, communicating, measuring, recording, and amplifying device. The system is a physical door that receives power & data feed, and is configured to be used as a chassis where electronic modules can be inserted, for enhanced home design, or home automation/security/entertainment applications. The door can be a “traffic” door interior or exterior, and includes closet doors, within homes, apartment buildings, office buildings, public buildings, or industrial sites. It could be installed in new constructions or as a replacement to an existing unit.

The door system can be placed in existing door locations, or be built as new construction to be optimally functioning as an integrated home system, on multiple residence levels or office environments to network together. The door system can be controlled via smartphone and allows for some apps to be developed, or direct touch control, or voice recognition. The modular door system allows multiple skins or surfaces that can be easily replaced or altered. The modular door system provides a hub or portal of independent or connected electrically powered functioning devices either through a single operating system or independently. Using the sketch on how the doors would create a vertically and horizontally optimized network of wireless repeaters (field of use) something with an azimuthal or isotropic band or range. The modular door system provides and facilitates co-location of equipment or devices in the core of an interior or exterior door for either independent function or connectivity of equipment and devices both with each other or complimentary devices within the household or business environment. The modular door system can be placed in existing door locations, or be built as new construction to be optimally functioning as an integrated home system, on multiple residence levels or office environments to network together without the threat of obsolescence due to its accessibility. The modular door system extends the current function of a door which allows/prevents ingress and egress and provides privacy and noise control to a multi-device unit or series of units without compromising the current function. The modular door system can be assembled by a novice or general homeowner without the need for equipment. The modular door system provides virtually limitless options for small electrical devices to be co-located, networked, updated, customized, or designed based on this new base low voltage DC hub. Numerous alternative configurations of powered equipment or technology only limited by the physical size in width of a standard door (approximately 1.5 inches). A key feature is the access and more efficient use of “dead space or volume” in a common household or office/business environment. A key feature is an easily replaceable skin or surface face of the door to allow updating without complete replacement of the structure. The modular door system reduces waste and therefore is more economically friendly. A key feature is the modularity of the system—allowing on-site assembly and an alternate method of shipping. Another key feature is the size adaptability of the system to accommodate multiple configurations and various standard door openings, both rough and framed openings. The modular door system is readily compatible with varying door standards prevailing on the world markets today, while minimizing the amount of adaptations and deviations in the case of unique, customized dimensional requirements, by defining some common denominators that push said dimensional variations to vertical and horizontal extenders. The modular door system combines hardware, software, sensors and communication technologies by providing electrical power in the form of low voltage Direct Current electricity. The modular door system can act both as a door, a portal for data networking, storage and co-location of equipment, a home or office network by providing the easily accessible structure (spine) and power and wiring (nervous system) allowing the consumer to determine the number of senses the system wants. The modular door system may provide slow charging battery backups for key systems in the event of a power outage (charging of mobile phones, continuity of internet, modems and routers) as short term protection during a natural event, and for continuous security in the case where the system houses monitoring devices. The modular door system is applicable to any part of the real-estate process (before building, selling, buying, renting and occupying a space). The modular door system offers the capability of incorporating air sensors-allergen detectors into a door embodiment. The modular door system offers the capability of incorporating a voice-controlled assistant into a door embodiment. The modular door system offers the capability of incorporating a smoke/carbon dioxide detection device into a door embodiment. The modular door system offers the capability of incorporating a wireless signal repeater/enhancer into a door embodiment. The modular door system offers the capability of incorporating speakers into a door embodiment. The modular door system offers the capability of incorporating displays into a door embodiment. The modular door system offers the capability of incorporating device chargers, such as smartphones or tablets, into a door embodiment. The modular door system offers the capability of incorporating power storage into a door embodiment, whether for local power backup or working as a lithium-ion battery stationary energy storage network. The modular door system provides software that offers the capability to customize door skins.

The system provides a door that is configured in order to allow three major evolutions from what current doors available to the public can provide:

A. Dramatically enhanced flexibility in the definition by the customer of the door basic properties. After the door is installed, by applying a different set of options, the owner can elect to adjust any of its four intrinsic parameters

a. Acoustic performance

b. Fire-resistance rating

c. Mechanical integrity/Bullet resistance

d. External appearance:
traditional/non-traditional material (rubber, leather etc.)
complete flexibility in geometries
possibility to elect for blind panel vs. panels that allow openings
ease of integrating at will a wide array of visual enhancements into the said door openings (glass/lights/electric privacy glass, mirrors, etc.).

B. Within a private or commercial building, leveraging a network of doors, by allowing each system to carry an array of accessories, the performance of which can be dramatically enhanced by multiple, fixed and strategically distributed locations within the building, as well as constant power and data network access. Those accessories can be embarked on each individual door and include, among others:

a. medium range data (wifi-bluetooth-4G-5G) signal repeaters (or beacons)

b. security cameras-motion detectors

c. bi-directional microphones and temperature sensors

d. smoke-carbon monoxide detectors

e. backup batteries

f. module management system (power switch and micro-processor).

C. Configuring the system to be usable as an open chassis for any other device that is candidate for using the available distributed, data & power connected space, with added functionalities including, among others:

g. Entertainment (e.g. speakers and/or displays)

h. Network memory storage

i. Distributed power storage

j. Electronic noise cancelling devices

k. Voice-controlled assistants (such as Amazon's Alexa/Google's Home)

l. Mechanical door lock controllers

m. Pet access control

n. Air quality sensors—for allergens

o. Environment handlers (air purifiers, humidifiers, diffusers, electronic insect repellants . . . )

p. Home automation controls (e.g. thermostats, light switches)

q. Information centers (date, time, temperature, reminders)

r. Phone/Tablet charging station

s. Sensors/detectors: door motion, room infra-red, radiation, seismic,

t. Recognition pads, such as Badge Biometric/visual recognition

u. Voice activated or voice recognition devices

v. Any small to medium size electronic device (Philips Hue, smartphone-to-TV relay, Z-wave hub such as Vera).

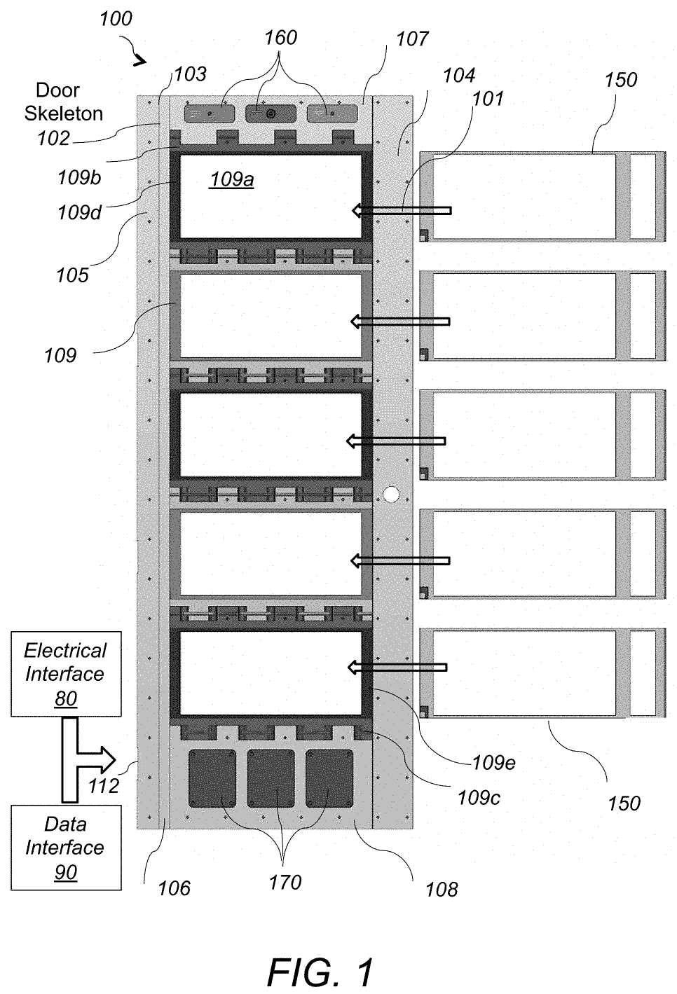

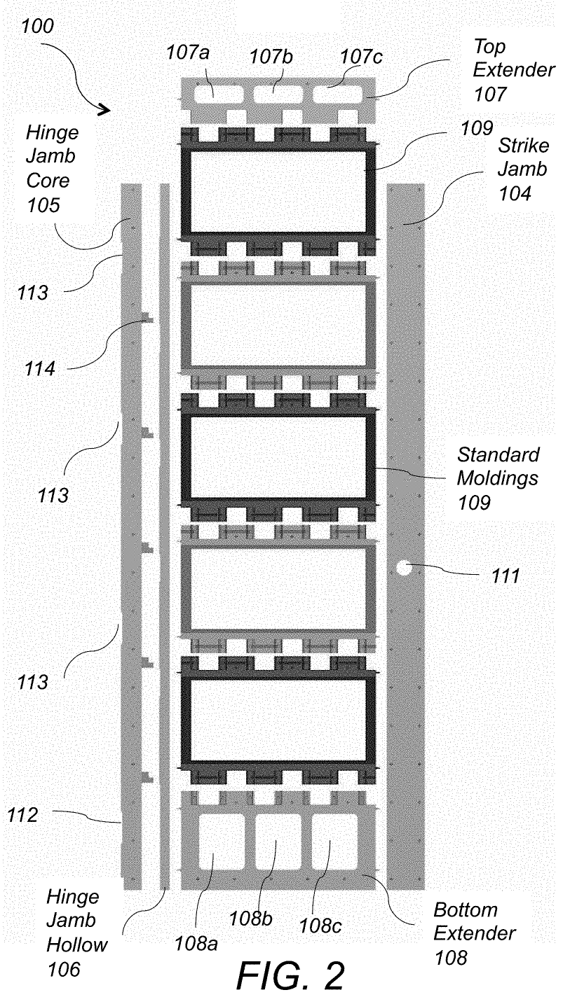

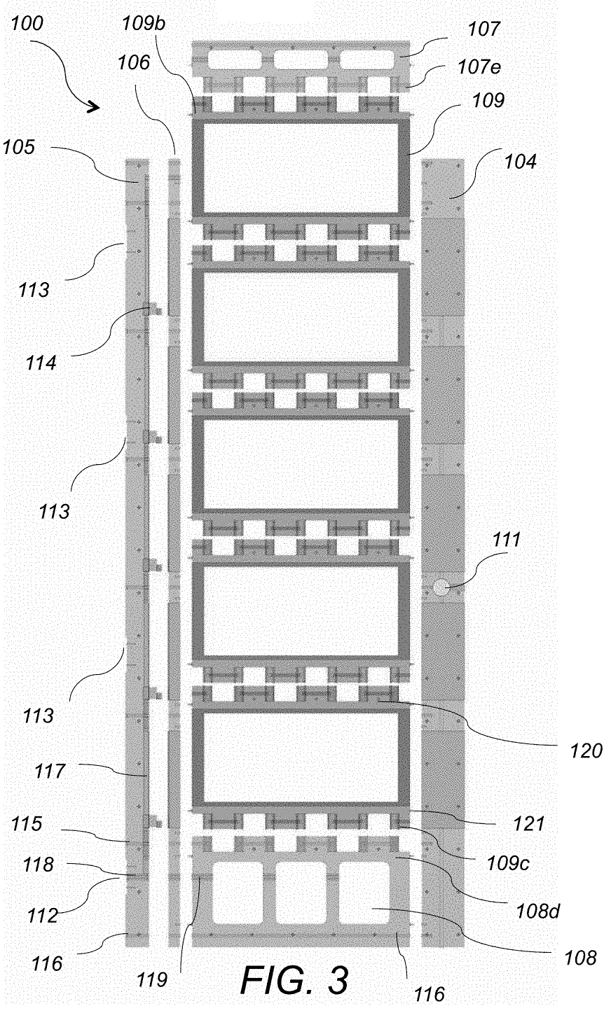

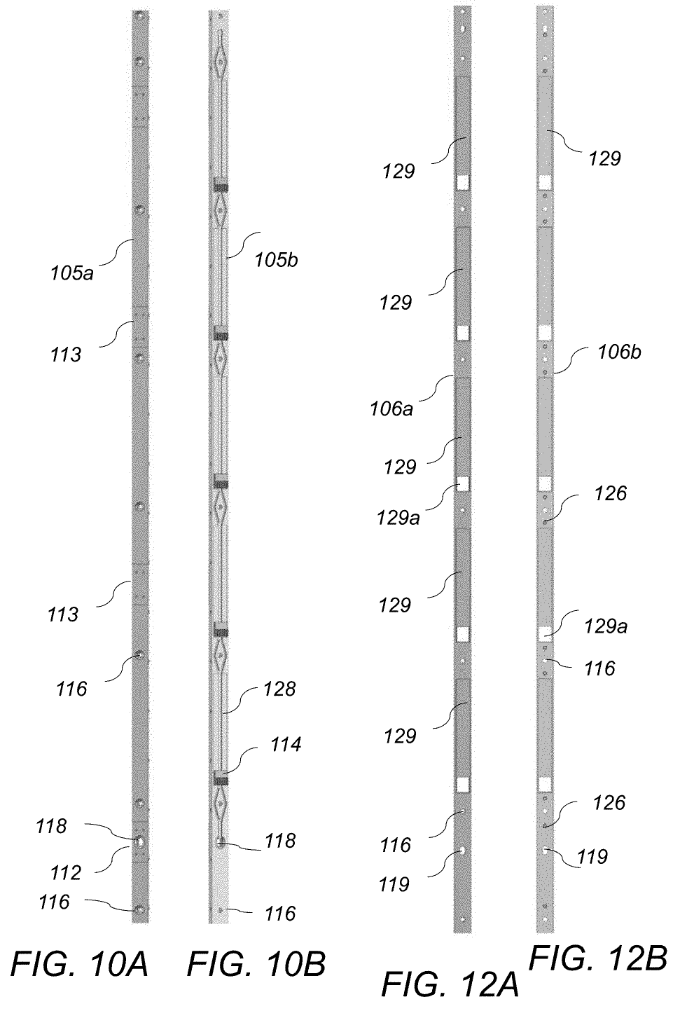

Referring to FIG. 1-FIG. 10, a modular door structure 100 according to this invention includes a door skeleton 102 that receives inputs from an electrical interface 80 and a data interface 90 via a door hinge 112. In this embodiment, the electrical interface 80 and the data interface 90 are located outside of the door skeleton 102 and provide power and data into the door skeleton 102 via the hinge 112, respectively. The door skeleton 102 is composed of modular structures that include a strike jamb 104, a hinge jamb 103, a top extender 107, a bottom extender 108, standard moldings 109, and module trays 150. Standard moldings 109 are designed to interdigitate at the top and the bottom sides with each other and thereby they form the center portion of the door skeleton 102. The top side 109b of the standard molding 109 that is located at the top of the door intedigitates with the bottom side 107e of the top extender 107 and the bottom side 109c of the standard molding 109 that is located at the bottom of the door interdigitates with the top 108d of the bottom extender 108. Hinge jamb 103 attaches to the hinge sides 109d of the standard moldings 109 and strike jamb 104 attaches to the strike sides 109e of the standard moldings 109. Each standard molding 109 includes a central opening 109a that is sized and dimensioned to receive a module tray 150. Module trays 150 are designed to slide into openings 109a from the side of the strike jamb 104 along the direction 101, as shown in FIG. 1.

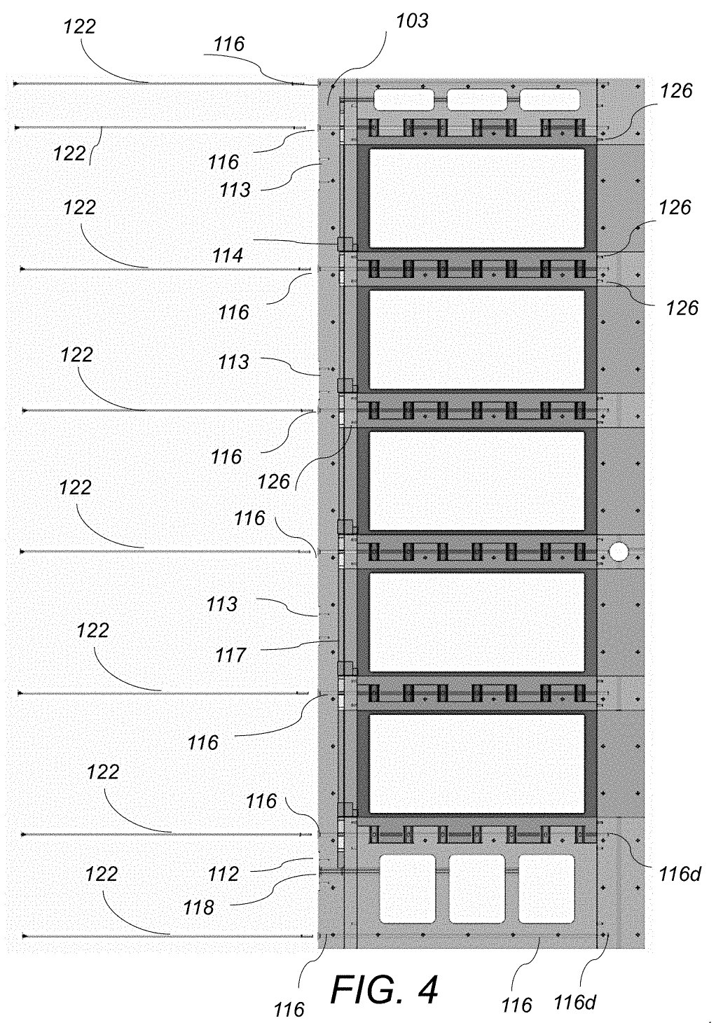

Once assembled, the modular door components 103, 104, 107, 108 and 109 are secured in place with holding rods 122 that are designed to pass through holding rod shafts 116 that extend from the hinge jamb 103, across the top and/or bottom sides of the standard molding frame 109, to the strike jamb 104, as shown in FIG. 4.

The assembled modular door structure 100 attaches to a doorframe via two, or three or four hinges 112, 113. In this embodiment, hinges 113 are used purely for mechanical attachment and hinge 12 is also used to provide power and data to the door frame. Hinge 12 includes a feedthrough opening 118, through which flexible power and data cables pass to connect the outside electrical power source 80 and data interface relay 90 to the inside of the door skeleton 102. In one example, the electrical power source 80 and the data interface 90 are provided by an inverted power outlet combined with a powerline-type data converter, thus allowing Ethernet to use the electrical circuit.

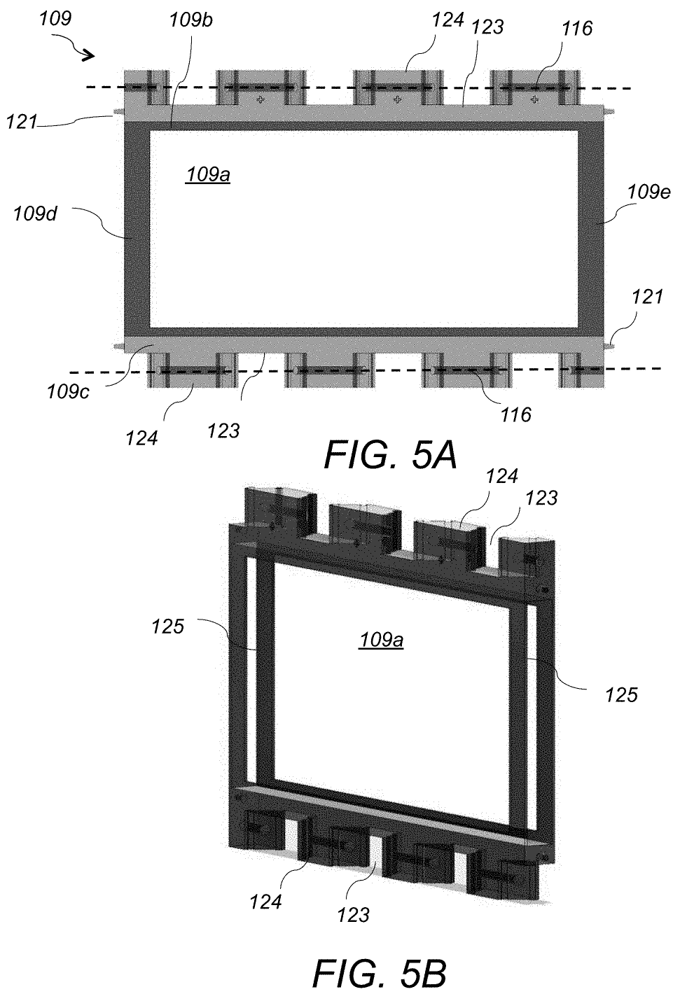

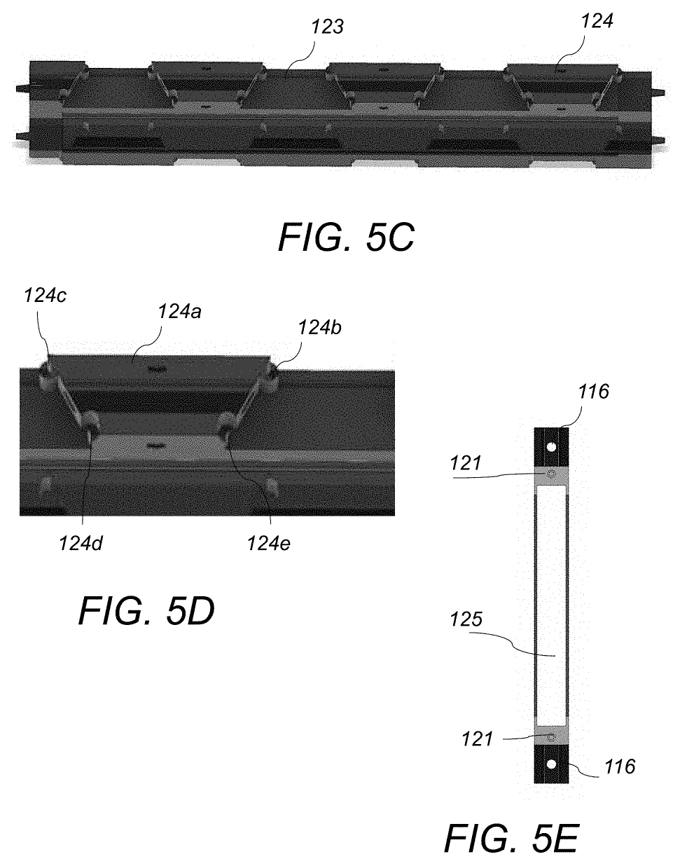

Referring to FIG. 5A-FIG. 5E, each standard molding 109 includes a top side 109b, a bottom side 109c, a hinge side 109d, and a strike side 109e. The four sides form a frame that surrounds the central opening 109a. The top and bottom sides 109b, 109c include crenellations 124 that are separated by gaps 123. Each crenellation 124 includes a trapezoid shaped main block 124a, two protrusions (jaws) 124b, 124c, and two depressions (jaw receptors) 124d, 124d. Each crenellation also includes a through opening (shaft) 116 that extends laterally through the main block 124a and is dimensioned to receive the holding rod 122. The insertion of the holding rod 122 into the opening 116 secures two adjacent moldings 109 together and prevents lateral slippage and/or angling of the moldings 109. Holding rod 122 also attaches the hinge side 109d of the molding 109 to the hinge jamb 103 and the strike side 109e of the molding 109 to the strike jamb 104. Hinge side 109d and strike side 109c also include top and bottom pegs 121 that are inserted into corresponding openings 126 in the hinge jamb 103 and the strike jamb 104, respectively. In this embodiment, pegs 121 are conically shaped and are inserted into conically shaped openings. Pegs 121 provide high level of positioning precision during the system assembly. As the hinge jamb 103 and the strike jamb 104 are pushed to the hinge side 109d of the moldings and to the strike side 109e of the moldings, respectively, a potential imperfect adherence between two adjacent moldings can be detected and corrected, due to the conic shape of the pegs 121 and peg receiving openings 126. The pegs 121 also provide an additional barrier against potential deformation of the assembled door with time.

Once the holding rods 122 are inserted into openings 116, the five molding bodies 109 behave mechanically as a single, perfectly rectangular body, which precludes the possibility of sagging of the system through its lifetime. Each standard molding 109 also includes a rectangular shaped through-opening 125 at strike side 109e that extends through the center 109a and through the hinge side 109d. Openings 125 are shaped and dimensioned to allow the module tray 150 to slide through and be positioned and held within the central opening 109a.

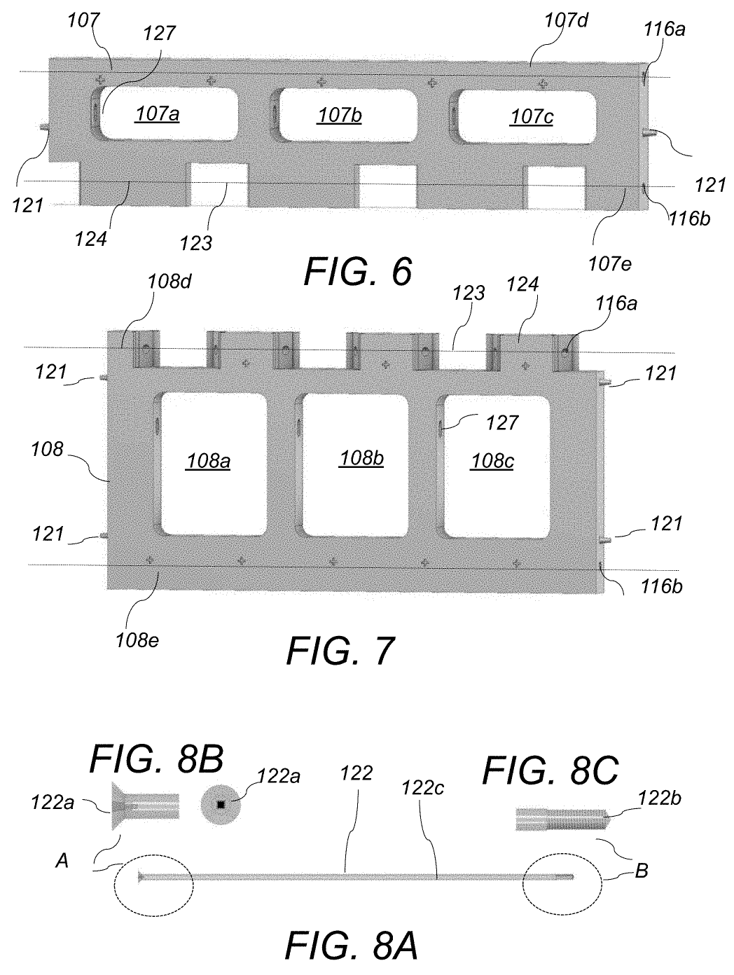

Top extender 107 and bottom extender 108 represent the vertical terminations of the central door assembly. The top extender 107 features crenellations 124 and gaps 123 on the bottom surface 107e, one dedicated rod shaft 116a, one shared rod shaft 116b, three accessory compartments 107a-107c, a pair of alignment pegs 121, and an opening 127 extending laterally into and through the accessory compartments, as shown in FIG. 6. The bottom extender 108 features crenellations 124 and gaps 123 on the top surface 108d, one dedicated rod shaft 116a, one shared rod shaft 116b, three accessory compartments 108a-108c, two pairs of alignment pegs 121, and an opening 127 extending laterally into and through the accessory compartments, as shown in FIG. 7. As was mentioned above, the top side 109b of the standard molding 109 that is located at the top of the door intedigitates with the bottom side 107e of the top extender 107 and the bottom side 109c of the standard molding 109 that is located at the bottom of the door interdigitates with the top 108d of the bottom extender 108. The rod shafts 116a, 116b are dimensioned to receive the holding rods 122. The lateral extending opening 127 allows passage and communication of cables between the accessory compartments. Openings 127 may also be used for air circulation applications for modules and accessories that require air circulation.

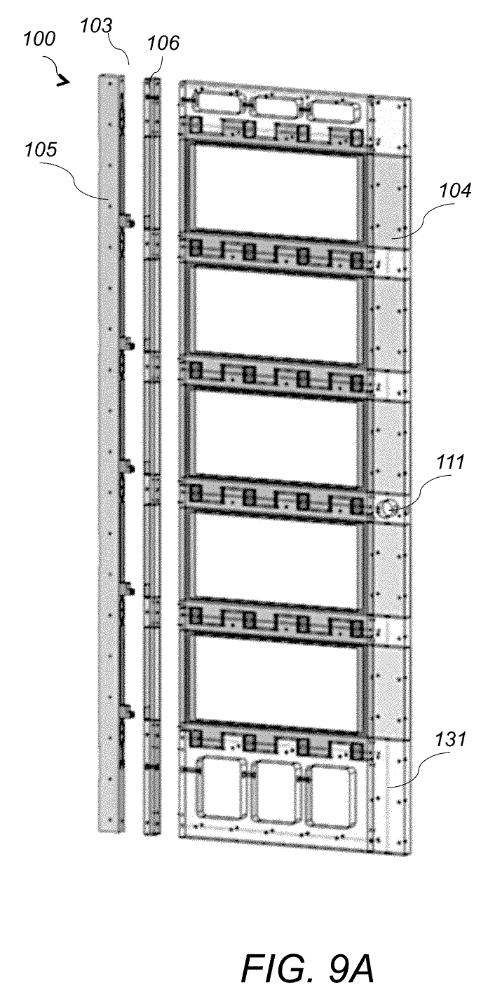

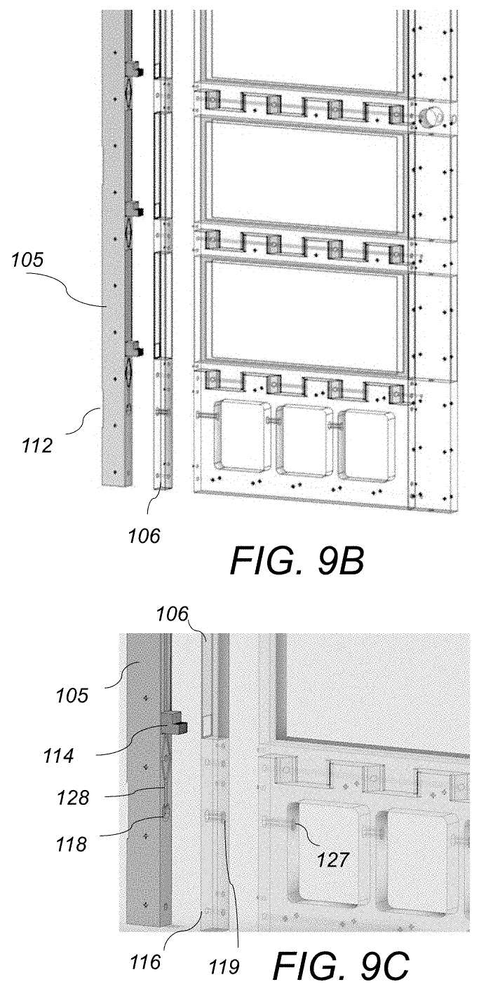

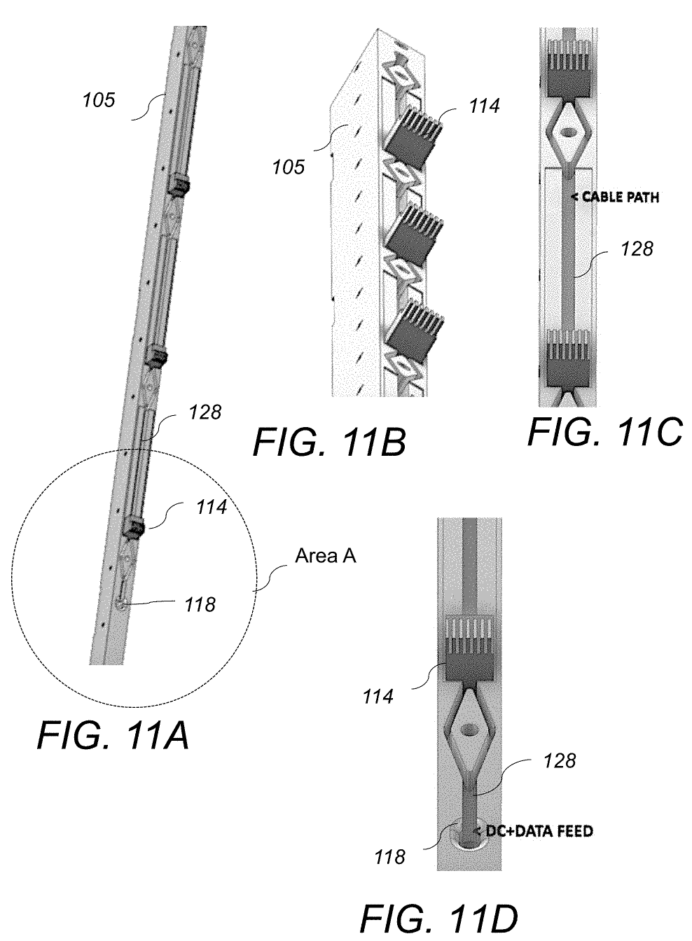

Referring to FIG. 9A-FIG. 11D, hinge jamb 103 includes a hinge jamb core member 105 and a hinge jamb hollow member 106. Hinge jamb core member 105 and hinge jamb hollow member 106 are vertically extending bars that are held together against the jamb side 109d of the moldings 109 once the door is assembled. Hinge jamb core member 105 is solid and includes hinge landing areas 112, 113 on the side 105a opposite to the door body, a cable path 128 on the side 105b next to the door body, eight holding rod cavities 116 that are countersunk on the side 105a opposite to the door body, one data and power entry point 118 at the level of the power hinge 112, and five male connector sockets 114 each providing two connections to the module trays 150. The hinge jamb hollow member 106 is hollow and includes eight holding rod cavities 116, one data-power cavity 119, conic openings 126 that are configured to receive the central moldings pegs 121, five tray landing cavities 129 forming the back of the modular tray 150 landing and allowing for the core hinge jamb connector 114 to come through opening 129a. The hollow hinge jamb 106 plays a key role in the safe circulation of cables in the “spine” of the system.

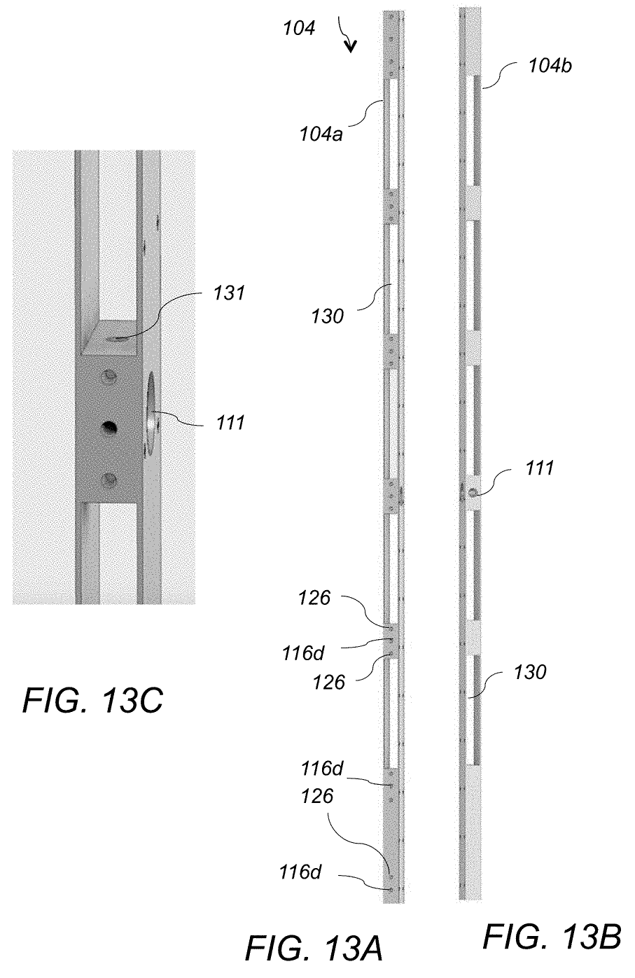

Referring to FIG. 13A-FIG. 13C, strike jamb 104 includes thirteen cone-shaped alignment peg anchor cavities 126 on the door side 104a, a knob apparatus opening 111, and five vertical slots 130 that are dimensioned to allow the five modular trays 150 to slide through the strike jamb side 104b. Strike jamb 104 also includes a vertical opening 131 (shown in FIG. 9A and FIG. 13C) that allows communication between the knob cavity 111 and all the lateral tray modules 150 for 3-bolt lock safety applications. Opening 131 is also used for air circulation.

The entirety of the door skeleton 102 is held in the assembled position by a number of holding rods 122 in the range between 3 and 8. Referring to FIG. 8A-FIG. 8C, each holding rod 122 includes a countersunk head 122a, an elongated shaft 122c and a threaded tip 122b. Holding rod 122 is dimensioned to pass through the openings 116, 116a, 116b that extend through the hinge jamb 103, moldings 109, top extender 107, and bottom extender 108. The threaded tip 122b of rod 122 engages a threaded opening 116d that is formed in the strike jamb 104.

Dimensional flexibility of the door 100 is provided in the vertical direction by the top extender 107 and the bottom extender 108 and in the horizontal direction by the hinge core jamb 103 and the strike jamb 104.

In one example, the standard moldings 109 are made of high density polyethylene (HDPE) or acrylonitrile butadiene styrene (ABS) and the top extender, bottom extender, hinge jamb and strike jamb are made of metal. In some examples the cavities of the skeleton 102 are filled with materials that improve acoustic performance or provide acoustic insulation. In other examples the cavities of the skeleton 102 are filled with fire resistant materials.

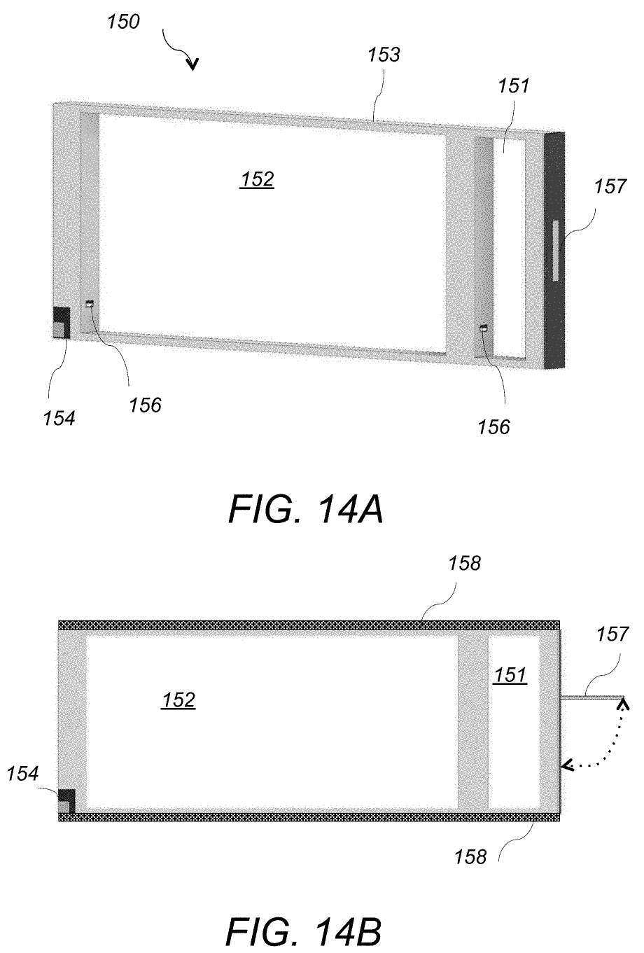

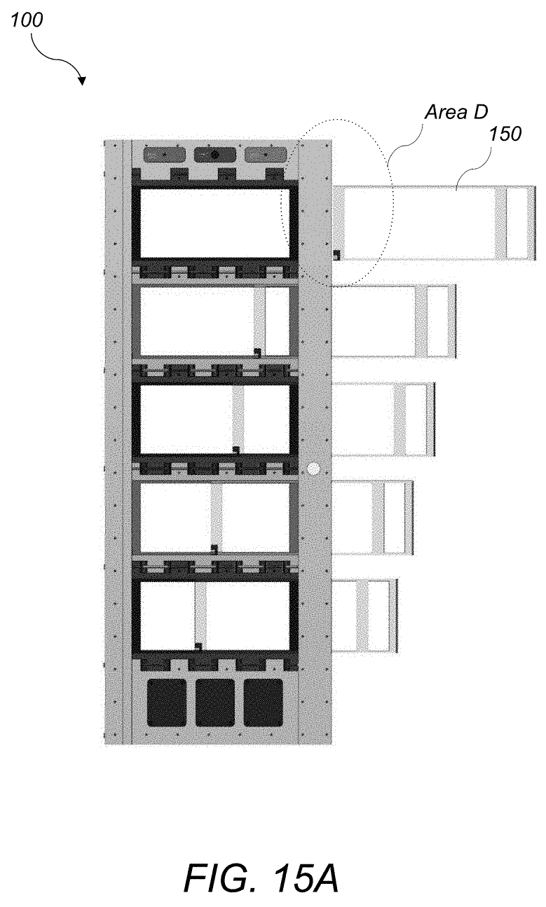

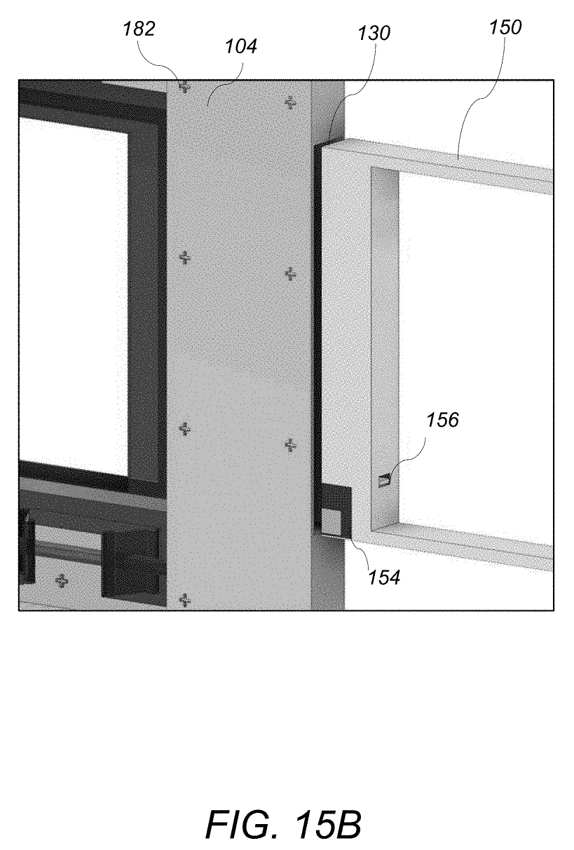

Referring to FIG. 14A-15B, module tray 150 includes a rectangular frame 153 that has a central opening 152 and a lateral opening 151. Module tray 150 also includes a female connector 154, USB connectors 156 and a lever 157 that swings out and is used to pull out the tray. Module trays 150 are designed to be fully extracted from the strike jamb side of the door. Each Module tray can be individually extracted, unloaded, reloaded and put back in place with no contingency on skin removal, and while the rest of the door remains fully functional, as shown in FIG. 15A. Full insertion of the module tray 150 creates a contact between the male connector 114 (located in the hinge jamb) and the tray's female connector 154. Each connector is designed to handle two USB 3.1 capacities ran in parallel that connect to the power and data sockets 156 located in the central 152 and lateral 151 openings. The connectors 114/154 are “dock station” type and apply a relative mechanical grip on the tray. The module trays 150 are secured in full insert position via a lock/unlock system that is activated by a small lever bar located on the exterior of the tray. In other embodiments the module trays 150 are secured in position via a “push-lock”/“push-unlock” system. The locking mechanisms are located either on the front side or the back side or the tray itself. Contact and smooth sliding between the standard molding top 109b and bottom 109c, and the module tray top and bottom “rail”, respectively, is provided by a smooth material interface 158, shown in FIG. 14B.

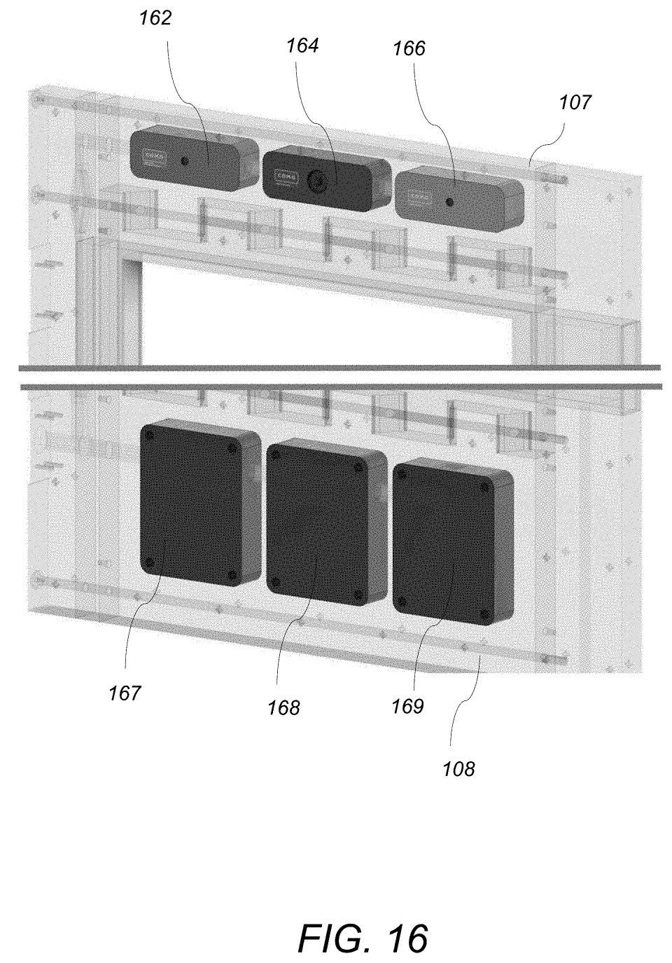

Referring to FIG. 16, top extender 107 includes three functional modules 162, 164, 166, located in the corresponding openings 107a, 107b, 107c. Modules 162, 164, 166 equip the door with network transmission and sensing capabilities. In one example, module 162 is a wireless network repeater and includes a digital data transmission antenna that creates a moderate power-moderate radius-high reliability hot spot that relays the wireless zone it creates to the home network via a wired, secured, network. Module 162 also includes a bi-directional microphone that enables voice recognition and noise detection to other modules. Module 164 includes a bi-directional camera, which can be down-activated as a motion detector. Module 166 includes a smoke detector, a carbon monoxide sensing unit, a temperature detector, and a stand alone sound alarm.

The bottom extender 108 includes three functional modules 167, 168, 169, located in the corresponding openings 108a, 108b, 108c. Module 167 includes a module manager that distributes the incoming power to the various locations within the door perimeter. Module 168 includes a microprocessing unit, which manages data traffic between the door components and the network, e.g. communication of sensor data. Module 169 includes a battery that allows the system to work independently and to provide emergency power during power outages for phone charging or light, among others.

The current wiring and cabling configuration of the door aims at reducing the risk of the door system becoming obsolescent early in its lifetime. As the user is enabled to permanently acquire the latest functionalities to embark on his system, a wiring/cabling upgrade, although feasible, is far less within reach. In order to reduce the odds that wiring becomes a bottleneck, each standard module is fed independently by a USB 3.1 (or equivalent) cable standard.

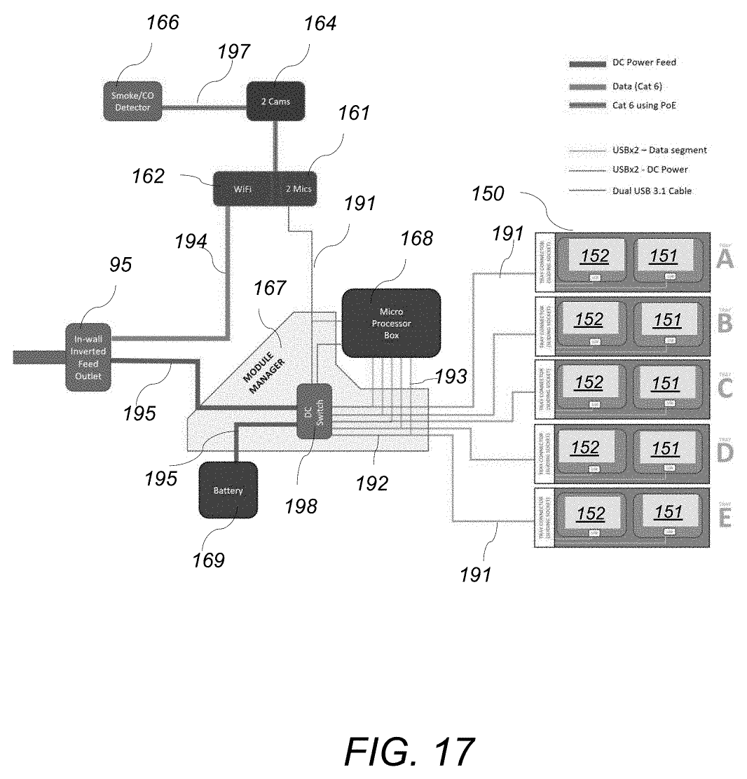

Referring to FIG. 17, data flows directly (i.e. without going through the processor 168) between the wireless signal repeater 162 and the wired network 95 that is external to the door, using RJ45/CAT6 Ethernet cable 194. The microprocessor 168 is an intermediate for all data coming from and to the modules trays 150 via lines 191. The microprocessor 168 can also direct the power switch/module manager 167 to turn any of the devices power on or off. A power switch 198 receives a DC power feed from the wall connector 95 or the battery 169, and distributes the power to modules 150 and the other components. Within the module manager 167, power and data feeds are combined, into ten separate USB 3.1 cable standard arrangements 191, 192, 193, such as AVG 28 copper, feeding each separate module space.

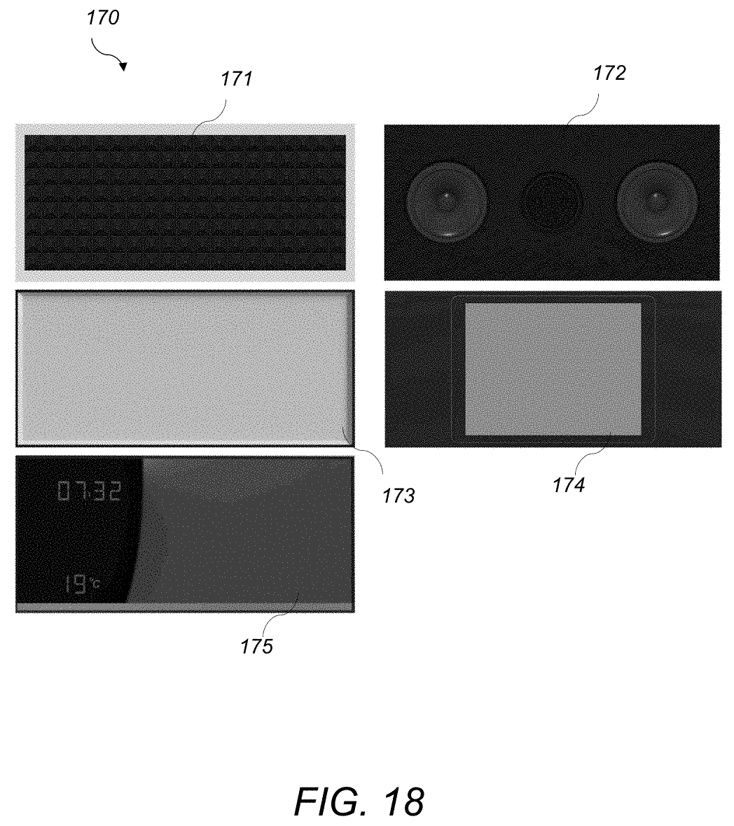

Each module tray 150 is configured to hold modules that are dimensioned to fit within the openings 152, 151. The modules are developed within dimensional, thermal and electrical/network specifications. Central openings 152 are configured to accommodate central modules with at least one visible face that can serve decorative or entertainment purposes. Referring to FIG. 18, examples of such modules include acoustic panels 171, glass 173 (transparent, colored, opaque, frosted, engraved, stained), electric privacy glass (EPG), touch screens 175, lights, mirror, mirror with integrated, LED lights, LED lights, LED mirrors, speakers 172, displays, TV screens, voice controlled assistants (Alexa, Google Home), tablet holder 174, network memory storage, distributed power storage, electronic noise cancelling devices, mechanical door lock controllers, pet access control, air quality/allergen sensors, environment handlers (air purifiers, humidifiers, diffusers, electronic insect repellants), home automation controls (thermostats, lights switches) information centers (date, time, temperature, calendar, reminders) 175, phone/tablet charging stations, sensors and detectors (door motion, room infra-red, radiation, seismic detectors) recognition pads (Badge, biometric, visual recognition), voice activated and voice recognition devices, and any small to medium size electronic device (Philips Hue, smartphone-to-TV relay, Z-wave hub such as Vera), among others. Some modules serving purely functional purposes and requiring either more space (e.g. a larger ion-lithium battery) or air access (e.g. an industrial air purifier needing several square inches of air intake/outlet) may also benefit from central locations.

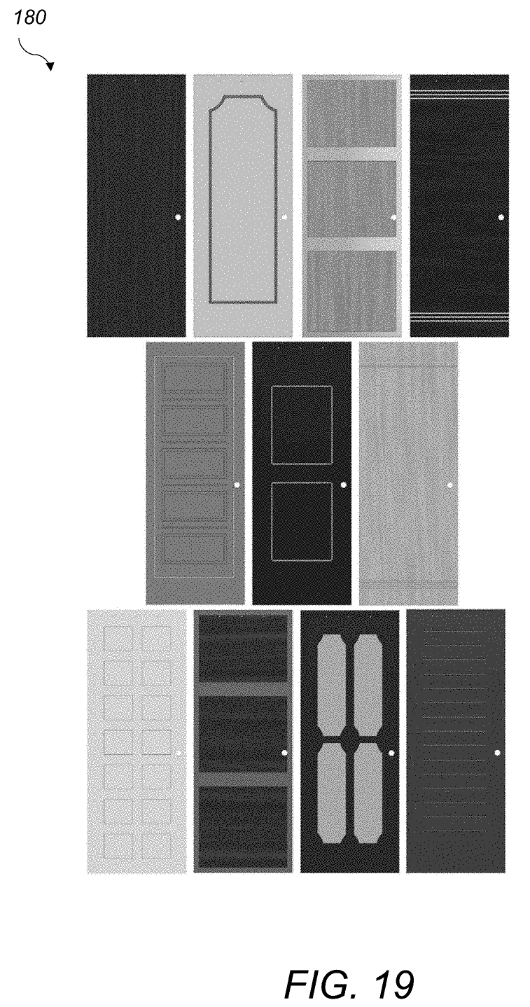

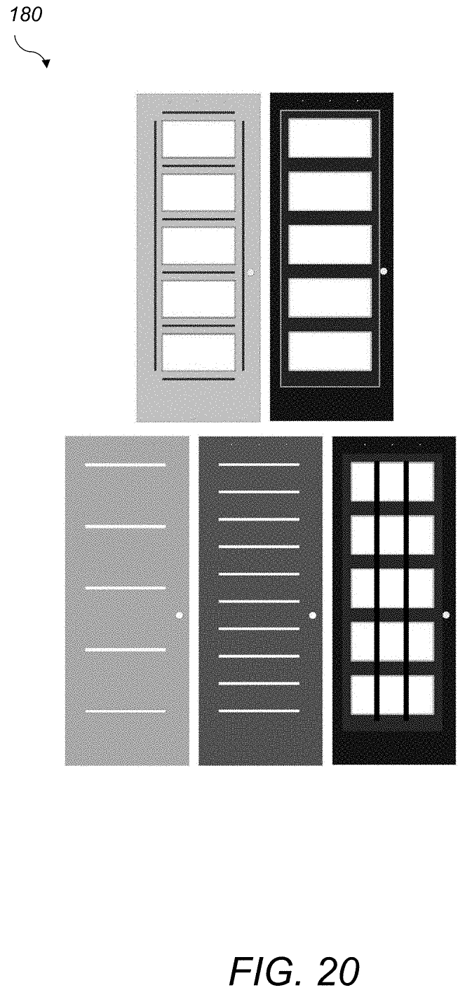

The outer surfaces of the door may be covered with various types of skins or coverings. Referring to FIG. 19 and FIG. 20, skins 180 include single panels, or multiple panels.

Even within a fixed dimensional specification, the skin “catalogue offering” that can be applied to this modular concept cannot fully leverage the virtual infinity of combinations of materials (wood veneer, paint, rubber, leather, metal, fabric . . . ), geometries (classical, modern, moldings, raised panes, recessed panes, etc . . . ) and added electric features (glass, EPG, lights, etc . . . ). The anticipation is that a venue will be opened for people that acquire modular doors to customize their door skin design.

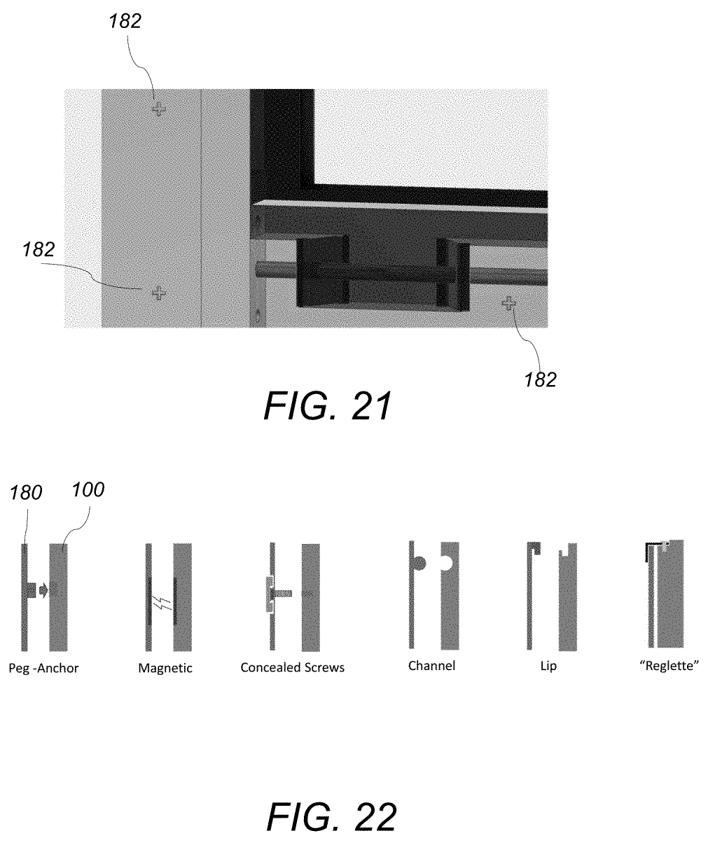

The skins 180 are attached to the door skeleton 102 via several mechanisms for skin attachments. Referring to FIG. 21 and FIG. 22, in one embodiment, an x-shaped peg & peg-hole anchoring system is used. Cross or x-shaped cavities 182 are stamped at regular intervals on the skeleton body 102, with the anticipation that anchoring approximately one third of them would suffice to hold a one-piece skin firmly into place. In other embodiments, skins 180 are attached via magnets, concealed screws, channels, lip, or reglettes, among others, as shown in FIG. 22.

In one example, the door skeleton 102 has a width of 762 mm, a height of 2032 mm, and a thickness of 36 mm. The module opening 109a has a width of 496 mm, a height of 278 mm and a thickness of 30 mm. The cable channel height is 178 cm.

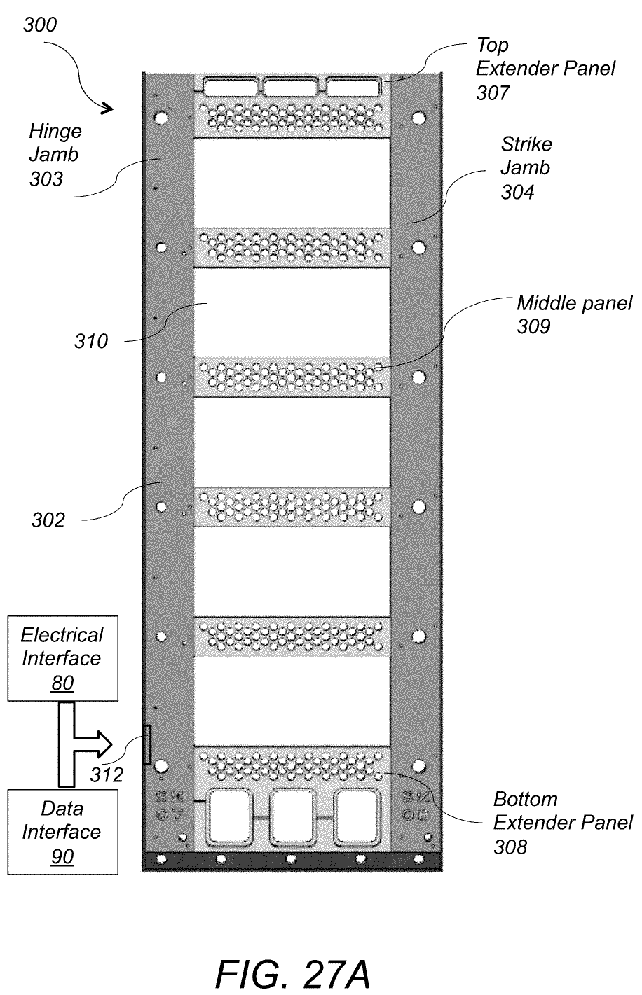

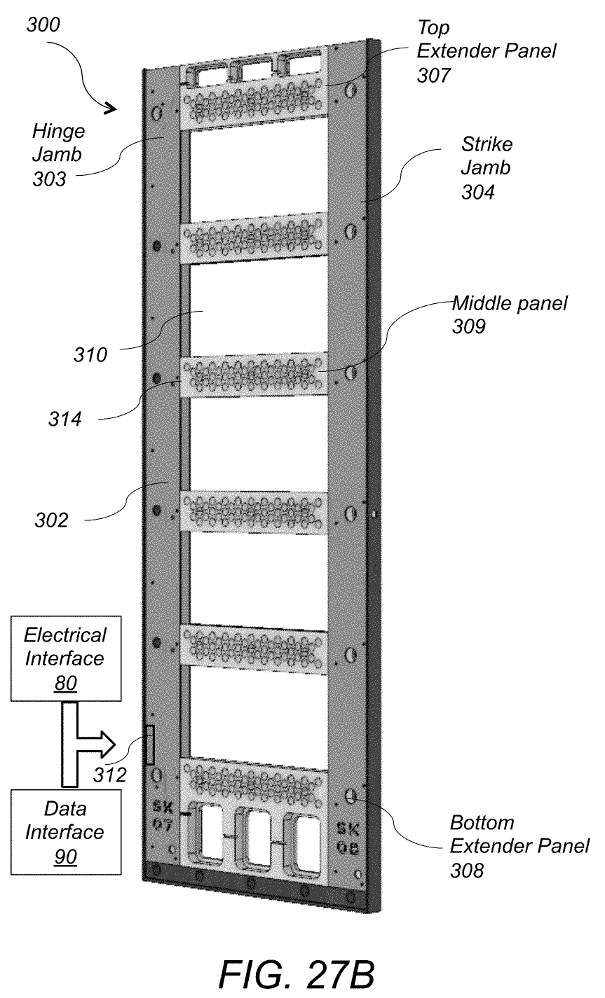

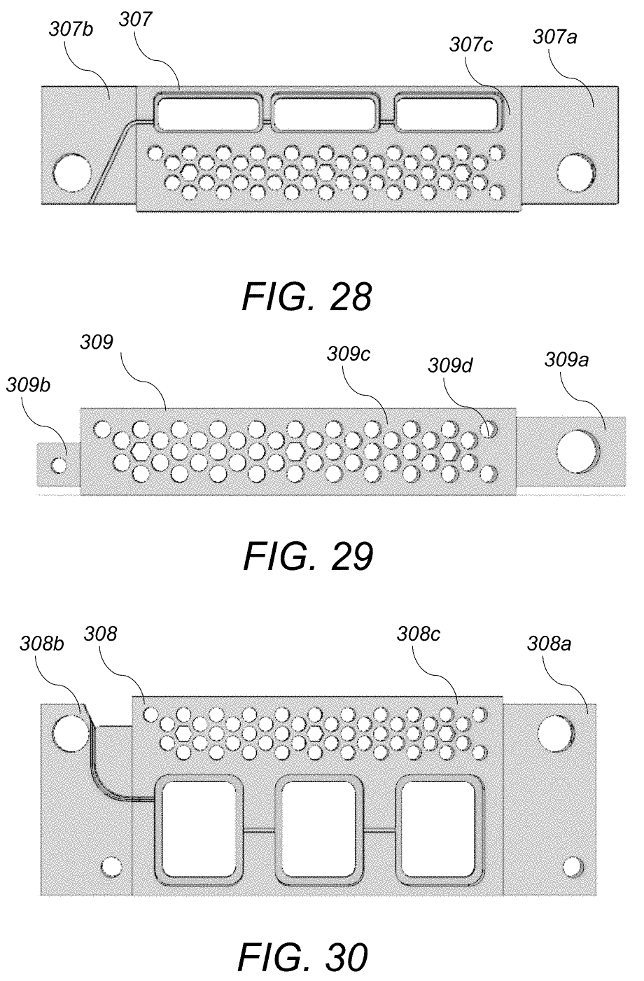

Referring to FIG. 27A-FIG. 30, in another embodiment, a modular door structure 300 according to this invention includes a door skeleton 302 that receives inputs from an electrical interface 80 and a data interface 90 via a door hinge 312. The door skeleton 302 is composed of modular structures that include a strike jamb 304, a hinge jamb 303, a top extender panel 307, a bottom extender panel 308, and middle panels 309. Top extender panel 307, bottom extender panel 308, and middle panels 309 are designed to attach to the hinge jamb 303 and strike jamb 304 via mortise and tenon joints. As shown in FIG. 28-FIG. 30, panels 307, 308 and 309 include a center portion 307c, 308c, 309c, left tenon 307b, 308b, 309b and right tenon 307a, 308a, 309a, respectively. Tenons 307a, 307b, 308a, 308b, 309a, 309b, are shaped and sized to fit within mortises (openings) 314 formed on the inner sides of the hinge jamb 303 and strike jamb 304, shown in FIG. 27B. Central openings 310 are formed between two panels and they are sized and shaped to receive a module tray 150. Module trays 150 are designed to slide into openings 310 from the side of the strike jamb 304 along the direction 101, as shown in FIG. 1.

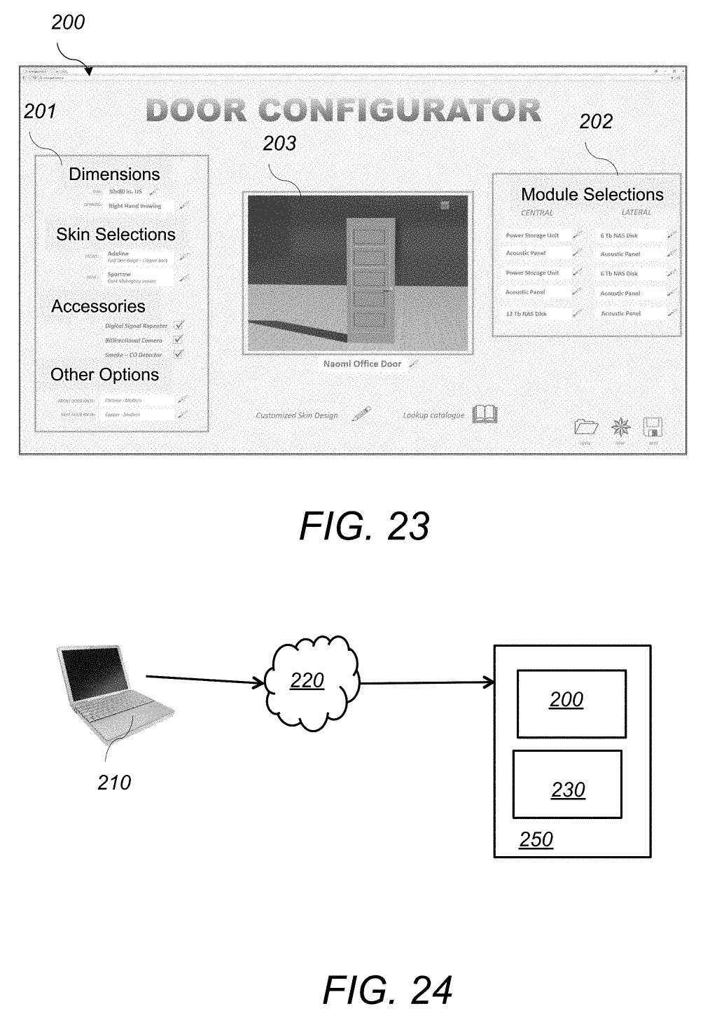

The invention also provides a method for a customer to design a modular door via an online web application. Referring to FIG. 23 and FIG. 24, customer 210 logs into server 250 via a network connection 220 and runs a modular door ordering application 200. Application 200 provides online door configuration, design and simulation services. Customer 210 has the option to consult an online catalogue 201, select door dimensions, skins, accessories and modules 202, and then test and visualize online the selection of features 203, and potentially design custom skin variations. Customer 200 can also visualize how to optimize the home wireless network. Customer 200 also has the option to run a door control application 230 either locally or remotely via the network connection. The door control application 230 synchronizes and promotes collaboration between the various devices that are installed within the door. Through the mere physical co-location of the hardware, integration of several families of like sensors, detectors, and devices (cameras, temperature sensors, speakers, etc . . . ) is achieved and a fleet of “Door Network Devices” (DND) is created. Application 230 allows the user 210 to access all door capabilities within a network simultaneously, check on all the DND status (safety and security alerts, temperature reports, among others), and instruct them (speakers, screens, among others) to work more synchronously.

Referring to FIG. 26, an exemplary computer system 400 or network architecture that may be used to implement the system of the present invention includes a processor 420, first memory 430, second memory 440, I/O interface 450 and communications interface 460. All these computer components are connected via a bus 410. One or more processors 420 may be used. Processor 420 may be a special-purpose or a general-purpose processor. As shown in FIG. 26, bus 410 connects the processor 420 to various other components of the computer system 400. Bus 410 may also connect processor 420 to other components (not shown) such as, sensors, and servomechanisms. Bus 410 may also connect the processor 420 to other computer systems. Processor 420 can receive computer code via the bus 410. The term “computer code” includes applications, programs, instructions, signals and/or data, among others. Processor 420 executes the computer code and may further send the computer code via the bus 410 to other computer systems. One or more computer systems 400 may be used to carry out the computer executable instructions of this invention.

Computer system 400 may further include one or more memories, such as first memory 430 and second memory 440. First memory 430, second memory 440, or a combination thereof function as a computer usable storage medium to store and/or access computer code. The first memory 430 and second memory 440 may be random access memory (RAM), read-only memory (ROM), a mass storage device, or any combination thereof. As shown in FIG. 26, one embodiment of second memory 440 is a mass storage device 443. The mass storage device 443 includes storage drive 445 and storage media 447. Storage media 447 may or may not be removable from the storage drive 445. Mass storage devices 443 with storage media 447 that are removable, otherwise referred to as removable storage media, allow computer code to be transferred to and/or from the computer system 400. Mass storage device 443 may be a Compact Disc Read-Only Memory (“CDROM”), ZIP storage device, tape storage device, magnetic storage device, optical storage device, Micro-Electro-Mechanical Systems (“MEMS”), nanotechnological storage device, floppy storage device, hard disk device, USB drive, among others. Mass storage device 443 may also be program cartridges and cartridge interfaces, removable memory chips (such as an EPROM, or PROM) and associated sockets.

The computer system 400 may further include other means for computer code to be loaded into or removed from the computer system 400, such as the input/output (“I/O”) interface 450 and/or communications interface 460. Both the I/O interface 450 and the communications interface 460 allow computer code to be transferred between the computer system 400 and external devices including other computer systems. This transfer may be bi-directional or omni-direction to or from the computer system 400. Computer code transferred by the I/O interface 450 and the communications interface 460 are typically in the form of signals, which may be electronic, electromagnetic, optical, or other signals capable of being sent and/or received by the interfaces. These signals may be transmitted via a variety of modes including wire or cable, fiber optics, a phone line, a cellular phone link, infrared (“IR”), and radio frequency (“RF”) link, among others.

The I/O interface 450 may be any connection, wired or wireless, that allows the transfer of computer code. In one example, I/O interface 450 includes an analog or digital audio connection, digital video interface (“DVI”), video graphics adapter (“VGA”), musical instrument digital interface (“MIDI”), parallel connection, PS/2 connection, serial connection, universal serial bus connection (“USB”), IEEE1394 connection, PCMCIA slot and card, among others. In certain embodiments the I/O interface connects to an I/O unit 455 such as a user interface, monitor, speaker, printer, touch screen display, among others. Communications interface 460 may also be used to transfer computer code to computer system 400. Communication interfaces include a modem, network interface (such as an Ethernet card), wired or wireless systems (such as Wi-Fi, Bluetooth, and IR), local area networks, wide area networks, and intranets, among others.

The invention is also directed to computer products, otherwise referred to as computer program products, to provide software that includes computer code to the computer system 400. Processor 420 executes the computer code in order to implement the methods of the present invention. In one example, the methods according to the present invention may be implemented using software that includes the computer code that is loaded into the computer system 400 using a memory 430, 440 such as the mass storage drive 443, or through an I/O interface 450, communications interface 460, or any other interface with the computer system 400. The computer code in conjunction with the computer system 400 may perform any one of, or any combination of, the steps of any of the methods presented herein. The methods according to the present invention may be also performed automatically, or may be invoked by some form of manual intervention. The computer system 400, or network architecture, of FIG. 26 is provided only for purposes of illustration, such that the present invention is not limited to this specific embodiment.

Other embodiments include one or more of the following. In the current configuration, the system skeleton has been designed in a way that:

a) allows the system to be readily compatible with varying door standards prevailing on the world markets today, while minimizing the amount of adaptations and deviations in the case of unique, customized dimensional requirements, by defining some common denominators that push said dimensional variations to vertical and horizontal extenders,

b) breaks the system down into smaller dimension subcomponents in order to improve transportation and storage of the system before assembly and installation, as well as to optimize the manufacturing costs,

c) makes several types of upgrades easy to implement during the lifetime of the door:
modules can be modified by the end user in a simple (no tools required) extremely short operation
skins can be modified by the end user in a simple, short operation
accessories, cables and connectors can be replaced or upgraded on-site by a trained technician with reasonable ease.

Although the present design configuration features accessories and modules that are designed to be easily removable/interchangeable/upgradable, an approach could be adopted whereby less importance would be awarded to this flexibility, and where some of the modules and accessories would be fixed or more difficult, possibly impossible, once installed, to change by the user.

The current “Multibloc” design approach, prioritizes modularity, ease of use, ease of transportation, while maintaining the ultimate door sturdiness to a maximal level. The system is configured in order to allow the maximum level of modularity, adaptability and flexibility, having in mind existing functions that could be incorporated into a door chassis as well as anticipating (and leaving maximum flexibility for) those that could be the fruit of future home design and automation innovations. However, an approach that would favor a “Monobloc” skeleton, or reduce the number of components that make up the skeleton, or favor a certain type of material in order to answer a specific requirement, could also be adopted (sheet metal, steel, wood, composite materials etc . . . ).

For example, a re-engineered solid wood door that would allow for the incorporation of a wireless signal emitter and/or advanced design features such as lights or electric privacy glass would fall under the field of this invention.

In the present design configuration, the insertion of Modules is performed by sliding Module Trays through the side (strike jamb) of the door, rendering the substitution of one module by another as simple as the replacement of a printer ink cartridge. However, frontal insertion, while it would require the removal of at least one of the skins, is an option that could be preferred for some specific applications and would fall under the field of this invention.

In the present configuration, skins that determine the final appearance of the front and rear of the doors are assumed to be two distinct one-piece panels that attach to the front of the door, through a peg and peg anchor system that is built into the skeleton. In other embodiments, the skins are attached to the door skeleton via magnetic interfacing, or frontal and or lateral screws, either visible, or concealed with the use of a set of decorative devices (caps, bars or reglettes), mechanical holds to a set of grooves or channels built into the skeleton, and/or lateral attachment through a lip, as widely used for smart phone and tablet cases.

In some design configuration, the system includes 5 Module Trays that each offer 2 modules positions. In the final inserted position, one of the modules, can be rendered visible (if the skin geometry allows), and a substantially narrower one lands behind the door strike jamb. That configuration (5 large+5 small) is anticipated to allow a large number of interesting combinations of decorative (lights, electric privacy glass) and utilitarian modules, large (speakers or display) or small (knob control) in the likely best positions on the door space. That said, different layouts and numbers of modular spaces could be developed, depending on demand and technical margins and parameters. A less flexible configuration can be used with either reservation of available locations for later extension or reduced costs or complexity.

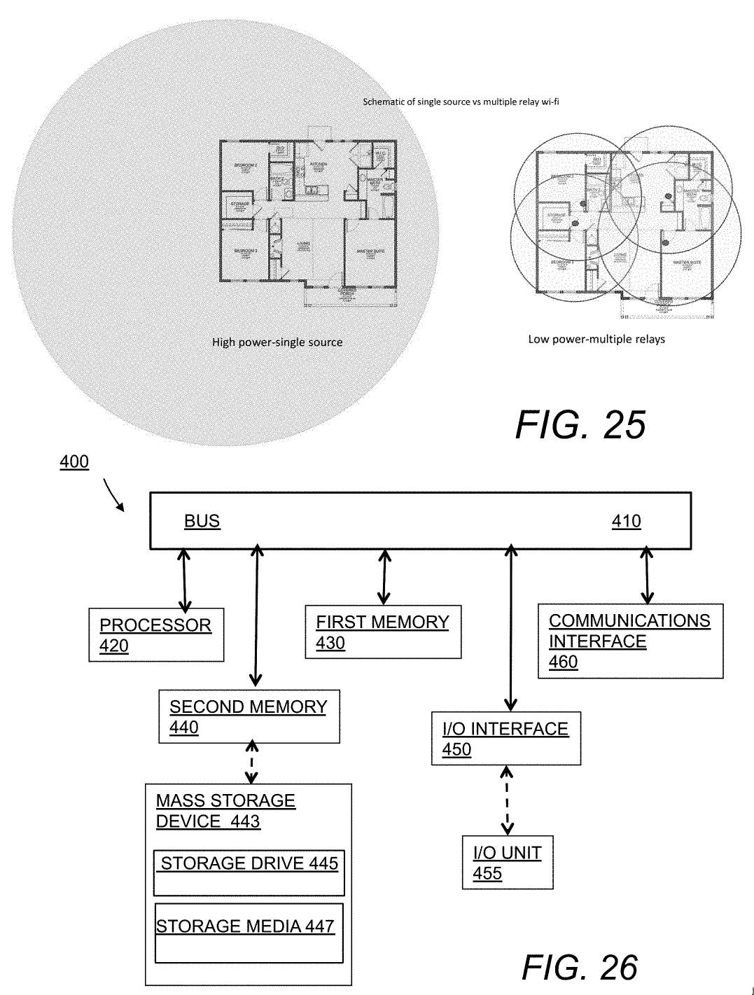

In the present design configuration, the system data and power feed is operated through one of 2-4 hinges (or edge of the door which is concealed when in the closed position) that allows a) a low voltage and b) a data feed to securely enter the door embodiment. Several alternatives may be used for both data and power:
Power: 1) a magnetic device allowing contact-free charging, 2) flexible tubing not going through hinges or edge of the door which is concealed when in the closed position, or 3) a “traditional” configuration, with visible wire connecting door to wall outlet
Data: the current design has set as a target that the door signal repeaters would create a medium radius hotspot (limited approximately to the distance to the next door in the network), and use wired connection to link that hotspot area to the rest of the network. There are three benefits to that approach:
it allows a reduction of the overall power level (vs. a high power-single source beam) thus reducing domestic exposure to potentially harmful levels of ambient Wi-Fi emission, shown in FIG. 25.
it allows a tighter control of the home emission zone, reducing the ability for neighbors or street-walking strangers to pick up a private home signal, and allowing to cut-off some areas in the house (e.g. toddler bedroom)
it provides ways to have a better signal distribution, getting around thick or concrete walls, and other undesired signal-altering barriers.

The present design configuration targets making those benefits available, and thus envisions tapping into the house electrical network to create a secured wired network and entirely eliminate the need for a high power Wi-Fi router. That said, a number of alternate possibilities exist, including an all-wireless supported grid of repeaters relaying peer to peer to a central node, however it would likely not provide the same communication speed

In the traditional, most common configuration whereby hinges are present on the side of the door body, they are assigned fixed landing positions on the hinge jamb. However, in order to increase the flexibility of the door and facilitate the adaptation of the skeleton into already installed door frames (in the case of remodeling), the option could be made available for customers adapt the hinge landing positions to their existing frame dimensions (thus minimizing rework of the frame itself).

A specific adaptation of the design is anticipated for:
“Pivot Hinge Doors” a.k.a. “Invisible Hinge doors” a.k.a. “wall flush” doors, where the system has a top and bottom pivot that sits centrally within the thickness of the frame and has no visible pivoting hardware along the jamb.
Pocket Doors, where the door body slides and disappears into the wall.
Multiple-Fold doors, where the door is made of two or more panels that pivot on each other and fold to one side of the doorway.
Double doors, where two vertical doors with distinct pivots meet in the middle of the opening when closed.
Dutch Doors, a door divided o two parts horizontally, allowing one half be shut and the other left open.

Several embodiments of the present invention have been described. Nevertheless, it will be understood that various modifications may be made without departing from the spirit and scope of the invention. Accordingly, other embodiments are within the scope of the following claims.

What is claimed is:

1. A system for a modular door for a building structure comprising:
a door skeleton comprising one or more removable modular structures;
an electrical interface;
a communication interface;
wherein at least one of the modular structures comprises one or more electronic components and at least one of the electronic components is configured to receive and transmit electrical signals and data via the electrical interface and the communication interface, respectively.

2. The system of claim 1, wherein the electrical interface and the communication interface are external to the door skeleton.

3. The system of claim 1, wherein the electrical interface and the communication interface are integrated within the door skeleton.

4. The system of claim 2, wherein the electrical interface and the communication interface transmit and receive electrical signals and data to the electronic components via an electrical connector and a communication connector, respectively, and wherein the electrical connector and the communication connector pass through a door hinge.

5. The system of claim 1, wherein one of the electronic components comprises a wireless network repeater.

6. The system of claim 1, wherein one of the electronic components comprises a microprocessor unit.

7. The system of claim 1, wherein the electronic components comprise one of a bi-directional camera, a bi-directional microphone, a motion detector, a smoke detector, a carbon monoxide detector, a temperature detector, a speaker, a display, a battery, a power module manager, a modem, a router, a memory storage device, software stored in a storage device, distributed power storage, electronic noise cancelling device, door lock controller, pet access control, air quality sensor, allergen sensor, environmental handler, thermostat, light switch, smart communication device, voice activated and voice recognition device, and a sound alarm.

8. The system of claim 1, wherein the door skeleton further comprises a strike jamb, a hinge jamb, a top extender, a bottom extender and one or more molding structures and wherein the molding structures interdigitate with each other and form a center portion of the door skeleton.

9. The system of claim 8, wherein at least one of the molding structures comprises a central opening and the central opening is sized to slidably receive one or more of the removable modular structures.

10. The system of claim 8, wherein the strike jamb, the hinge jamb, the top extender, the bottom extender and the one or more molding structures are held together via one or more rods.

11. The system of claim 8, wherein the strike jamb, the hinge jamb, the top extender, the bottom extender and the one or more molding structures are held together via mortise and tenon joints.

12. The system of claim 8, wherein each of the molding structures comprises one or more crenellations formed on a top surface and a bottom surface of the molding structure, and wherein adjacent crenellations are separated by a gap and wherein the gap is shaped and sized to receive a crenellation from an adjacent molding structure.

13. The system of claim 1, wherein at least one of the removable modular structures comprises a visible front surface and the visible front surface comprises one of an acoustic panel, glass, electric privacy glass, touch screen, lights, LED lights, mirror, LED mirror, display, a voice controlled assistant, information center, tablet holder, biometric recognition pad, voice activated device, voice recognition device, smartphone and smart tablet.

14. The system of claim 1, further comprising a door frame sized to receive the door skeleton and wherein the door frame is located in an existing building structure.

15. The system of claim 1, further comprising a door frame sized to receive the door skeleton and wherein the door frame is located in a new building structure.

16. The system of claim 1, further comprising a controller configured to control the one or more electronic components remotely, and wherein the controller comprises one of a smartphone, a tablet, a remote controller, or a computing device.

17. The system of claim 1, further comprising one or more skin surfaces configured to be applied onto the door skeleton's front and back surfaces.

18. The system of claim 9, wherein each removable modular structure comprises a power connector and a communication connector and the power connector and communication connector are configured to mate with a corresponding power connector and a corresponding communication connector, respectively, that are located on a surface of the hinge jamb, when the removable modular structure is fully inserted into a molding structure.

19. A method for a modular door for a building structure comprising:
providing a door skeleton comprising one or more removable modular structures;
providing an electrical interface;
providing a communication interface;
placing one or more electronic components within at least one of the removable modular structures, wherein at least one of the electronic components is configured to receive and transmit electrical signals and data via the electrical interface and the communication interface, respectively.

20. A method for configuring a modular door for a building structure comprising:
providing a door configuration design application configured to present various door configuration design parameters and to generate instructions for constructing a modular door configuration based on user input;
providing a computing system comprising at least a processor configured to execute computer-implemented instructions of the door configuration design application;
providing a user interface that displays the various door configuration design parameters, wherein the door configuration parameters comprise door skeletons and electronic components;
selecting a door skeleton comprising one or more removable modular structures;
selecting one or more electronic components and placing the one or more electronic components within at least one of the removable modular structures;
wherein at least one of the electronic components is configured to receive and transmit electrical signals and data via an electrical interface connector and a communication interface connector, respectively, and wherein the electrical interface connector and the communication interface connector are located within the door skeleton.

21. A system for configuring a modular door for a building structure comprising:
a door configuration design application configured to present various door configuration design parameters and to generate instructions for constructing a modular door configuration based on user input;
a computing system comprising at least a processor configured to execute computer-implemented instructions of the door configuration design application;
a user interface that displays the various door configuration design parameters, wherein the door configuration parameters comprise door skeletons and electronic components;
wherein a door skeleton comprises one or more removable modular structures and one or more electronic components located within at least one of the removable modular structures;
wherein at least one of the electronic components is configured to receive and transmit electrical signals and data via an electrical interface connector and a communication interface connector, respectively, and wherein the electrical interface connector and the communication interface connector are located within the door skeleton.
